(19) United States
(12) Patent Application Publication
(10) Pub. No.: US 2012/0220131 A1
(43) Pub. Date: Aug. 30, 2012

(54) METHOD FOR FABRICATING SEMICONDUCTOR DEVICE

(76) Inventor: Tae-Seung EOM, Gyeonggi-do (KR)

(21) Appl. No.: 13/333,961

(22) Filed: Dec. 21, 2011

(30) Foreign Application Priority Data
Feb. 28, 2011 (KR) 10-2011-0017665

(51) Int. Cl. H01L 21/311; H01L 21/31

(52) U.S. Cl. 438/702; 438/761; 257/E21.24; 257/E21.249

(57) ABSTRACT

A method for fabricating a semiconductor memory device includes forming a photoresist layer on a substrate, performing an exposure process such by illuminating a first area of the photoresist layer with a first amount of a light and illuminating a second area of the photoresist layer with a light of a second amount smaller than the first amount, removing the first area of the photoresist layer to form a photoresist pattern, and forming a capping layer on a surface of the photoresist pattern.

### CROSS-REFERENCE TO RELATED APPLICATIONS

The present application claims priority of Korean Patent Application No. 10-2011-0017665, filed on Feb. 28, 2011, which is incorporated herein by reference in its entirety.

### BACKGROUND

1. Field

Exemplary embodiments of the present invention relate to technology for fabricating a semiconductor device, and particularly, to a method for forming a contact hole of a semiconductor device using freezing double patterning technology (Freezing DPT).

2. Description of the Related Art

In the development of a semiconductor device, pattern shrinkage is the most important item to increase yield thereof. Due to the pattern shrinkage, however, it becomes difficult to form a contact hole in a semiconductor device of 40 nm or less. In order to form contact holes with a diameter and an interval of 40 nm or less, new patterning technology is being developed. In this regard, freezing double patterning technology (Freezing DPT) has been newly introduced.

FIG. 1A to FIG. 1D are plan views illustrating a process for forming a contact hole of a semiconductor device according to the conventional art, and FIG. 2A and FIG. 2B are images illustrating the features of the conventional art.

As illustrated in FIG. 1A, a line-type of a first photoresist pattern 11 extending in a first direction is formed on a substrate having a first area where contact holes are to be formed and a second area where no contact holes are formed, and simultaneously a second photoresist pattern 12 is formed to cover the most part of the second area shown in FIG. 1A. At this time, in order to increase the pattern uniformity, the first photoresist pattern 11 is expanded in the first direction to a certain portion of the second area.

As illustrated in FIG. 1B, a freezing material is coated on the structure including the first and second photoresist patterns 11 and 12, and a thermal treatment is performed to form a capping layer on the surface of the first photoresist pattern 11. The capping layer is generated when acid generated through a reaction between a photoresist layer and a light in an exposure process for forming a photoresist pattern reacts with the freezing material. Hereinafter, a reference numeral of the first photoresist pattern 11 provided with the capping layer will be changed to ‘11A’.

As illustrated in FIG. 1C, a line-type of a third photoresist pattern 13 extending in a second direction perpendicular to the first direction is formed on the structure including the first and second photoresist patterns 11A and 12, and simultaneously a fourth photoresist pattern 14 is formed to cover the most part of the second area. At this time, in order to increase the pattern uniformity, the third photoresist pattern 13 is expanded in the second direction a certain portion of the second area, and the first photoresist pattern 11A provided with the capping layer is not exposed to a light in the process for forming the third and fourth photoresist patterns 13 and 14.

Then, the substrate is etched using the first to fourth photoresist patterns 11A, 12, 13 and 14 as an etch barrier, thereby forming a plurality of contact holes 15 in the first area as illustrated in FIG. 1D. Then, the first to fourth photoresist patterns 11A, 12, 13 and 14 are removed.

However, in the conventional art, the first to fourth photoresist patterns 11A, 12, 13 and 14 are formed using a binary intensity mask (BIM), and a capping layer may not be formed on the surface of the second photoresist pattern 12 due to the characteristics of the binary intensity mask and the shape of the second photoresist pattern 12. Therefore, as indicated by reference numeral ‘X’ of FIG. 2A and reference numeral ‘Y’ of FIG. 2B, in the process for forming the third photoresist pattern 13, the second photoresist pattern 12 may be lost from the second area to which the third photoresist pattern 13 is expanded, so that a undesirable contact hole may be formed in the second area.

### SUMMARY

Exemplary embodiments of the present invention are directed to a method for fabricating a semiconductor device, which may prevent a contact hole from being formed improperly.

In accordance with an exemplary embodiment of the present invention, a method for fabricating a semiconductor memory device includes forming a photoresist layer on a substrate, performing an exposure process by illuminating a first area of the photoresist layer with a first amount of a light and illuminating a second area of the photoresist layer with a light of a second amount smaller than the first amount, removing the first area of the photoresist layer to form a photoresist pattern, and forming a capping layer on a surface of the photoresist pattern.

In accordance with an exemplary embodiment of the present invention, a method for fabricating a contact hole of a semiconductor memory device includes forming a photoresist layer on a substrate having a first area and a second area, performing an exposure process by illuminating an exposure area of the photoresist layer with a first amount of a light and illuminating a non-exposure area of the photoresist layer with a light of a second amount smaller than the first amount, removing the exposure area of the photoresist layer to form a first photoresist pattern in the first area and a part of the second area and simultaneously form a second photoresist pattern covering the other part of the second area, forming a capping layer on surfaces of the first and second photoresist patterns, forming a third photoresist pattern crossing the first photoresist pattern in the first area and a part of the second area of the substrate and simultaneously forming a fourth photoresist pattern covering the other part of the second area; and etching the substrate by using the first to fourth photoresist patterns as an etching barrier.

### BRIEF DESCRIPTION OF THE DRAWINGS

FIG. 1A to FIG. 1D are plan views illustrating a process for forming a contact hole of a semiconductor device according to the conventional art.

FIG. 2A and FIG. 2B are diagrams illustrating the features of the conventional art.

FIG. 3A is an explanatory diagram illustrating the degree of light transmission at a binary intensity mask and an attenuated phase shift mask.

FIG. 3B is a graph illustrating light transmittance at a binary intensity mask and an attenuated phase shift mask.

FIG. 4A to FIG. 4C are plan views illustrating a method for forming a contact hole of a semiconductor device in accordance with an exemplary embodiment of the present invention.

FIG. 5A to FIG. 5D are cross-sectional views showing a method for fabricating a photoresist pattern provided with a capping layer, which are taken along line I-I′ shown in FIG. 4A.

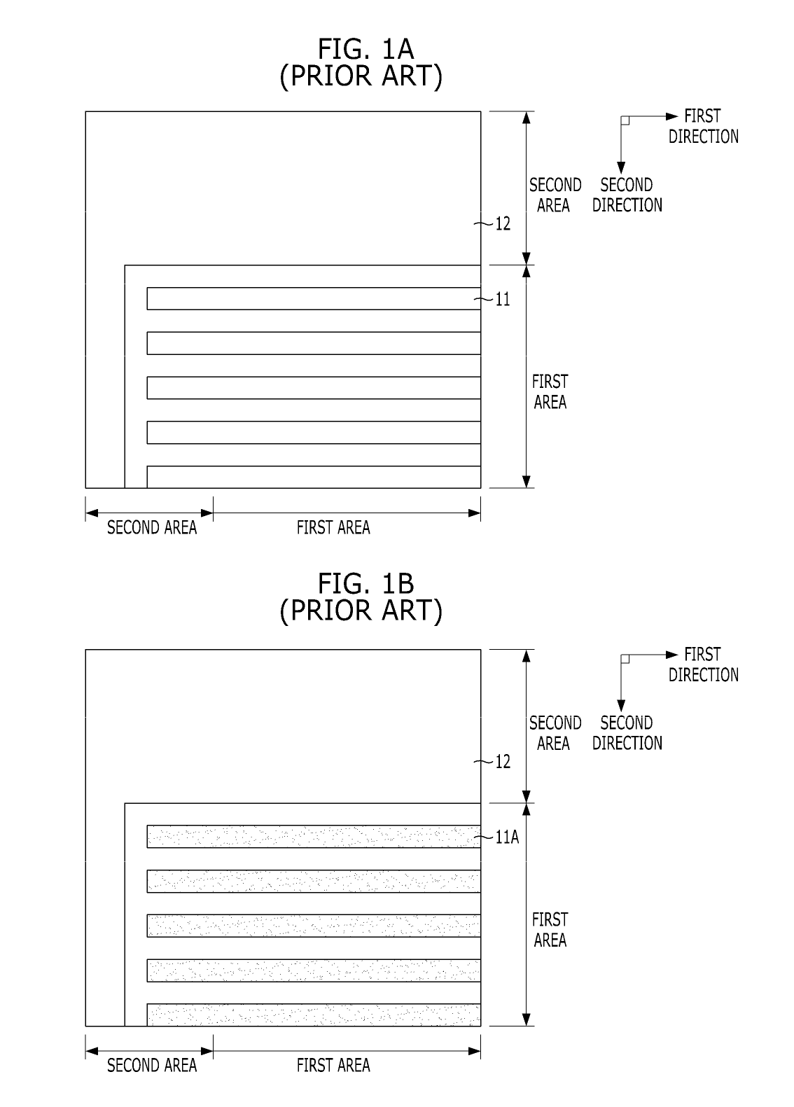

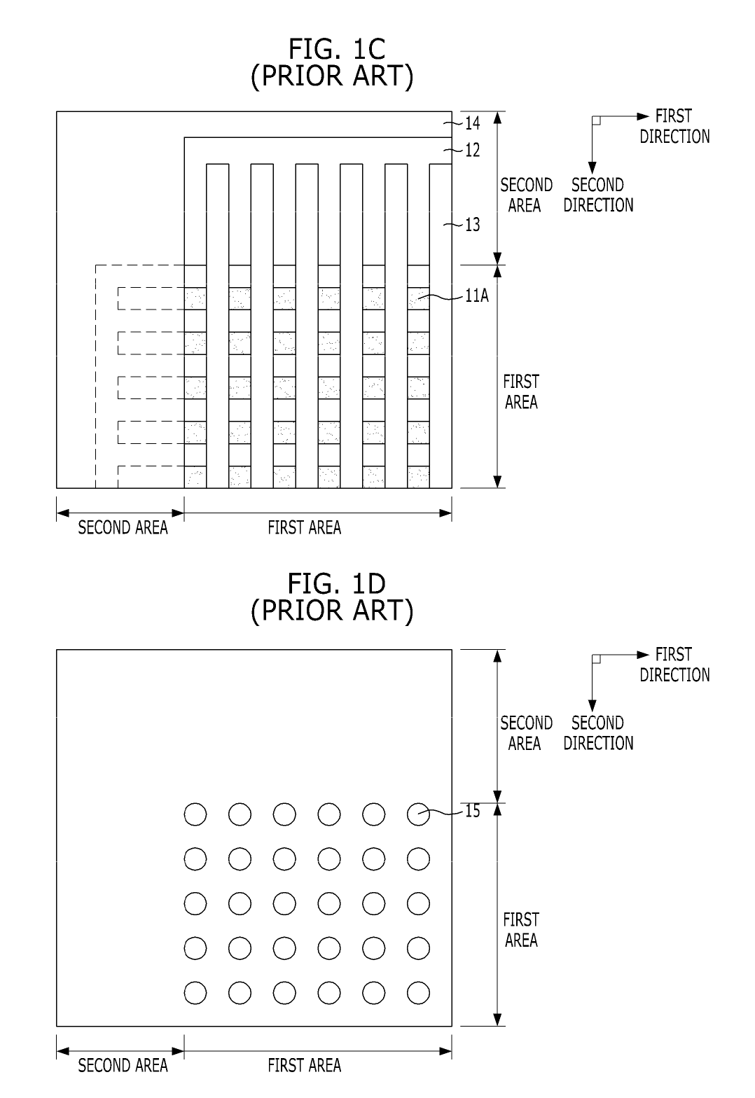

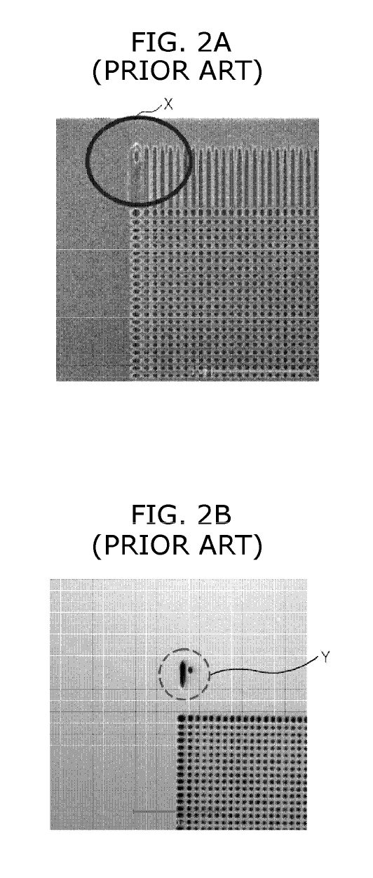

### DETAILED DESCRIPTION

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

The drawings are not necessarily to scale and in some instances, proportions may have been exaggerated in order to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

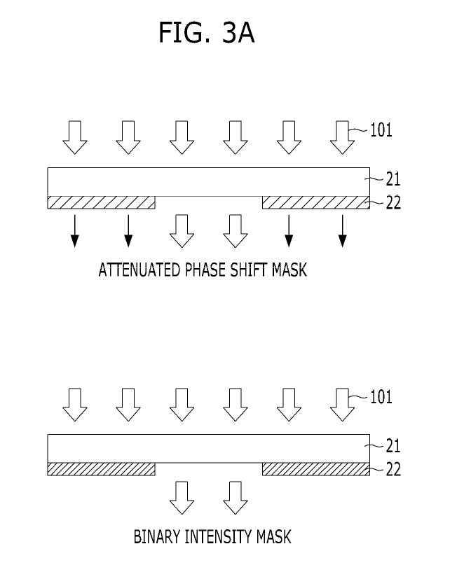

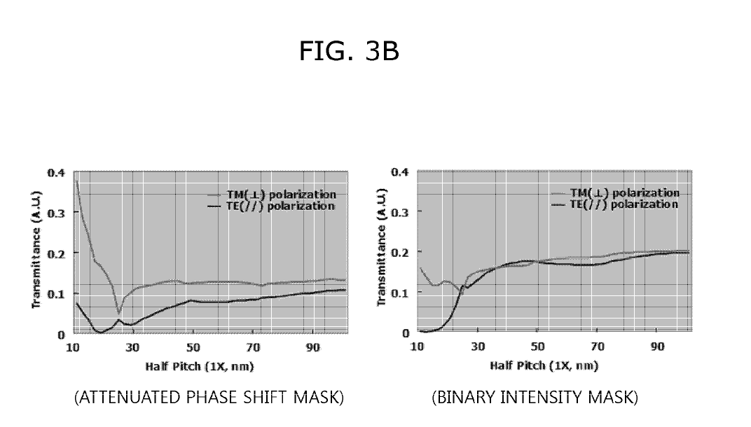

The present invention relates to a micro pattern formation method using freezing double patterning technology (Freezing DPT), and has a feature that a predetermined amount of light is also irradiated onto a non-exposure area other than an exposure area when an exposure process is performed on a photoresist layer, thereby inducing the generation of acid for forming a capping layer through a reaction with a freezing material. To this end, the present invention has another feature that an attenuated phase shift mask is used in order to irradiate/illuminate the non-exposure area other than the exposure area with a certain amount of light onto. Hereinafter, a binary intensity mask and an attenuated phase shift mask will be described by comparing them with each other with reference to FIG. 3A and FIG. 3B.

FIG. 3A is a diagram illustrating the degree of light transmission at a binary intensity mask and an attenuated phase shift mask, and FIG. 3B is a graph illustrating light transmittance at the binary intensity mask and the attenuated phase shift mask.

As illustrated in FIG. 3A and FIG. 3B, the attenuated phase shift mask and the binary intensity mask include light blocking patterns 22 formed on a light transmitting substrate 21, respectively. In the case of the binary intensity mask, an incident light 101 does not pass through the light blocking patterns 22. However, in the case of the attenuated phase shift mask, a part of the incident light 101 may pass through the light blocking patterns 22. This is caused by diffraction interference occurring when an interval/distance (or a line width of a pattern to be formed) between the light blocking patterns 22 is smaller than a wavelength of an exposure light source, which is a phenomenon occurring when the interval between the light blocking patterns 22 is equal to or less than 40 nm (refer to FIG. 3B).

Since the phenomenon that the part of the incident light 101 passes through the light blocking patterns 22 represents a reduction in the transmittance of a mask, the binary intensity mask has been used in order to form a pattern with a line width of 40 nm or less in the conventional art (refer to FIG. 3B). However, in the present invention, since a pattern with a line width of 40 nm or less is formed using the attenuated phase shift mask, acid may be generated in a non-exposure area of a photoresist layer by irradiating the area with a predetermined amount of light, thereby forming a capping layer on the entire surface of a photoresist pattern.

Hereinafter, the technical scope of the present invention will be described in detail through a method for forming a contact hole with a diameter and an interval of 40 nm or less in accordance with an exemplary embodiment of the present invention.

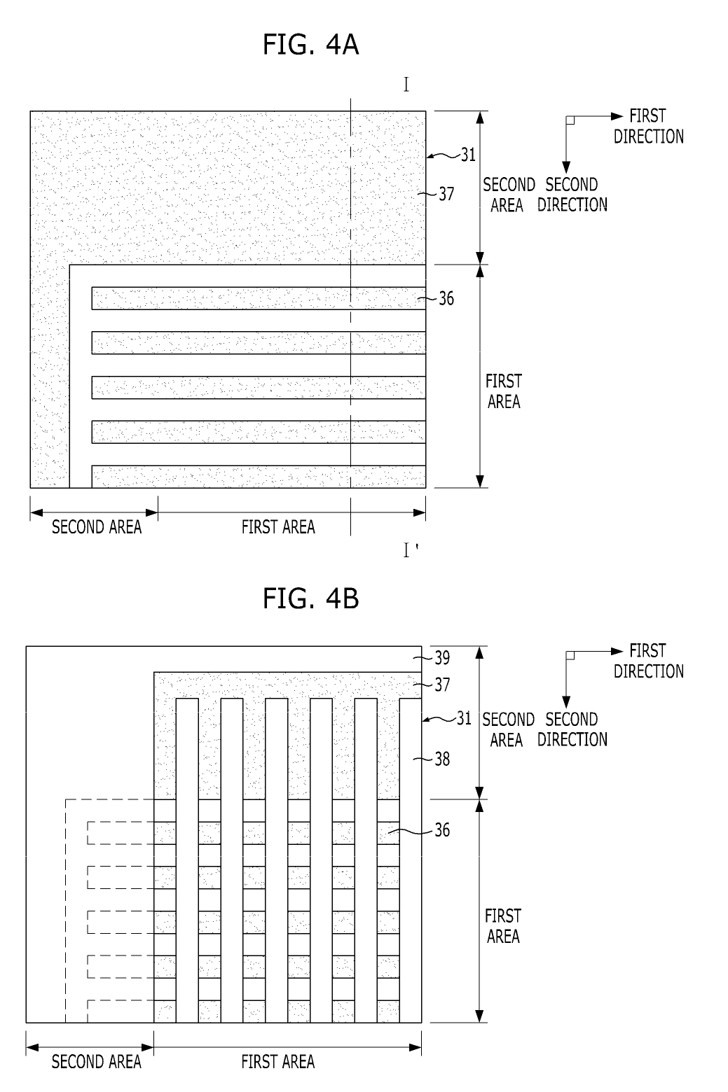

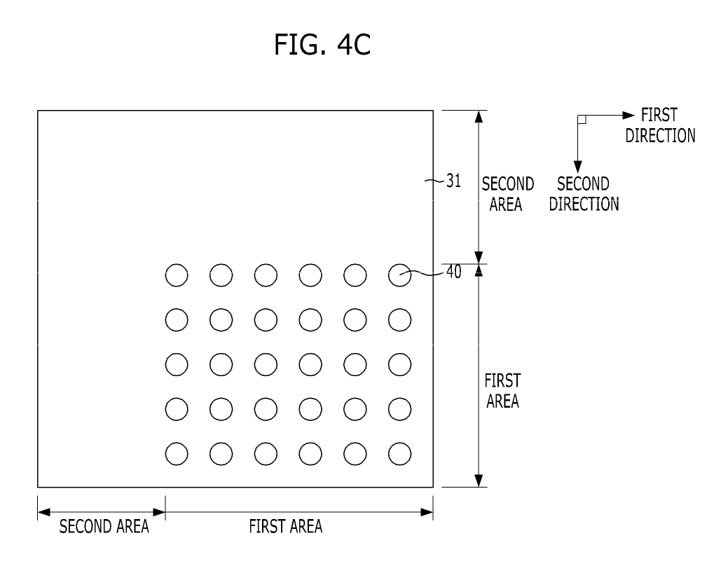

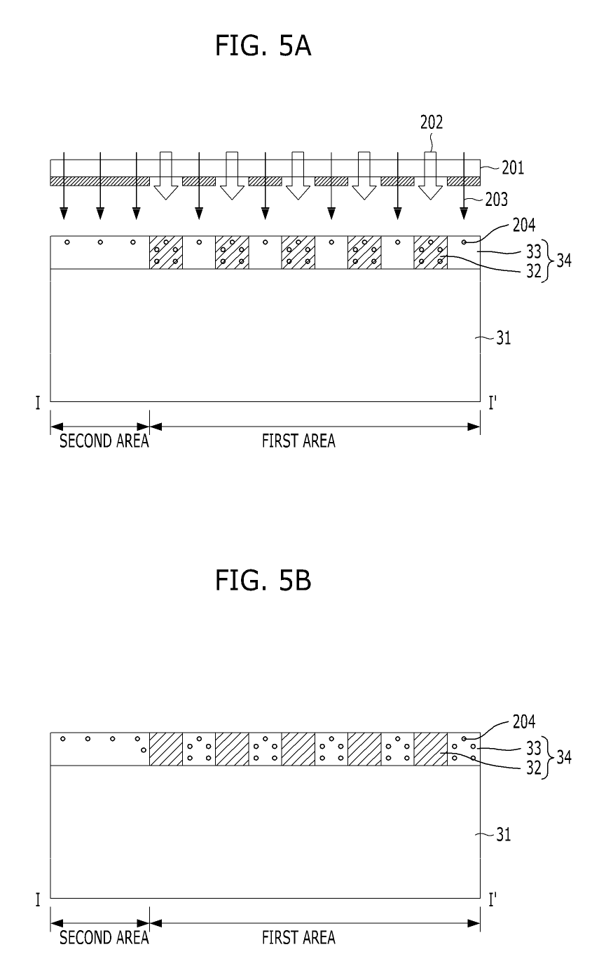

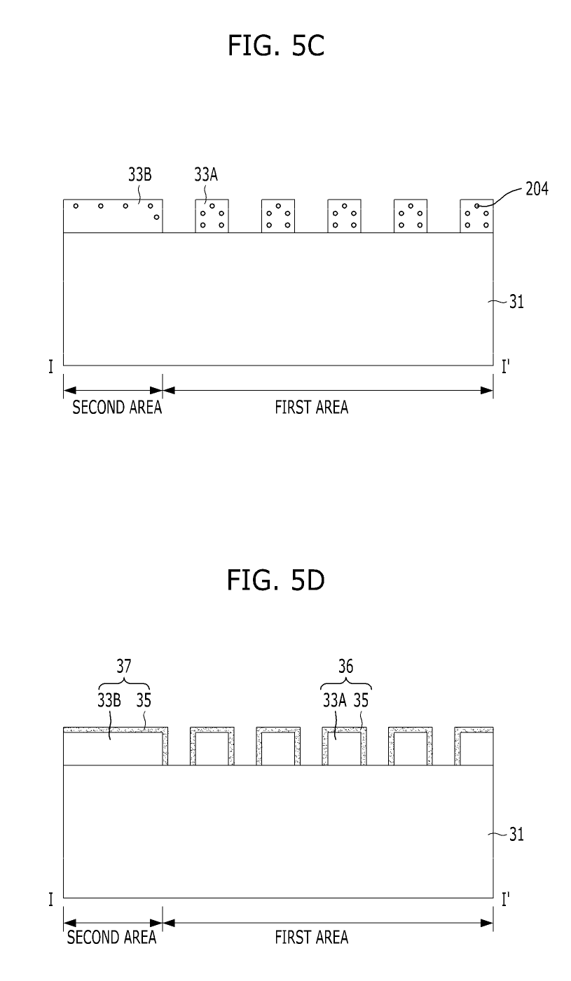

FIG. 4A to FIG. 4C are plan views illustrating a method for forming a contact hole of a semiconductor device in accordance with the exemplary embodiment of the present invention, and FIG. 5A to FIG. 5D are cross-sectional views a method for fabricating a photoresist pattern provided with a capping layer, which are taken along line I-I′ shown in FIG. 4A.

As illustrated in FIG. 4A, a line-type of a first photoresist pattern 33A extending in a first direction is formed on a substrate 31 having a first area where contact holes are to be formed and a second area where no contact holes are formed, and simultaneously a second photoresist pattern 33B is formed to cover a part of the second area. Then, a capping layer 35 is formed on the surfaces of the first and second photoresist patterns 33A and 33B. At this time, in order to ensure the pattern uniformity, the first photoresist pattern 33A is expanded in the first direction to the other part of the second area.

Hereinafter, a reference numeral of the first photoresist pattern 33A provided with the capping layer 35 will be changed to ‘36’, a reference numeral of the second photoresist pattern 33B provided with the capping layer 35 will be changed to ‘37’, and a process for forming the first and second photoresist patterns 36 and 37 provided with the capping layer 35 will be described in detail with reference to FIG. 5A to FIG. 5D.

As illustrated in FIG. 5A, a photoresist layer 34 is formed on the substrate 31 having the first area and the second area. The photoresist layer 34 may use a positive type. The first area where the contact holes are formed may be a cell area, and the second area where no contact holes are formed may be a peripheral circuit area.

An exposure process is performed using an attenuated phase shift mask 201 such that a light with a second amount 203 smaller than a first amount 202 of a light irradiated onto an exposure area 32 of the photoresist layer 34 is also irradiated onto a non-exposure area 33 of the photoresist layer 34. At this time, preferably, the second amount 203 of the light is in a range of 6% to 30% of the first amount 202 of the light. When the second amount 203 of the light is smaller than 6% of the first amount 202 of the light, a sufficient amount of acid may not be generated in the non-exposure area 33 of the photoresist layer 34. When the second amount 203 of the light exceeds 30% of the first amount 202 of the light, the non-exposure area 33 of the photoresist layer 34 may be lost in a subsequent development process.

As described above, as the exposure process is performed using the attenuated phase shift mask, acid 204 is generated in the exposure area 32 and the non-exposure area 33 of the photoresist layer 34. At this time, due to the difference between the amounts of the lights irradiated onto the photoresist layer 34, a large amount of acid 204 is generated in the exposure area 32, as compared with the non-exposure area 33 of the photoresist layer 34.

As illustrated in FIG. 5B, a thermal treatment is performed to diffuse the acid 204 generated in the exposure area 32 of the photoresist layer 34 into the non-exposure area 33 of the photoresist layer 34. This is for increasing the efficiency of a subsequent capping layer formation process and simultaneously performing the subsequent development process more easily.

As illustrated in FIG. 5C, the development process is performed to remove the exposure area 32 of the photoresist layer 34. At the time point at which the development process is completed, the non-exposure area of the photoresist layer remaining in the first area serves as the first photoresist pattern 33A, and the non-exposure area of the photoresist layer remaining in the second area serves as the second photoresist pattern 33B.

As illustrated in FIG. 5D, the capping layer 35 is formed on the surfaces of the first and second photoresist patterns 33A and 33B. The capping layer 35 may be formed through a series of processes for coating a freezing material on the structure including the substrate 31 provided with the first and second photoresist patterns 33A and 33B, performing a thermal treatment to form the capping layer 35 on the surfaces of the first and second photoresist patterns 33A and 33B, and removing a remaining freezing material after the capping layer 35 is formed.

Through the above-mentioned processes, the first photoresist pattern 36 and the second photoresist pattern 37 provided with the capping layer 35 may be formed.

As illustrated in FIG. 4B, a line-type of a third photoresist pattern 38 extending in a second direction perpendicular to the first direction is formed on the first area of the substrate 31 provided with the first and second photoresist patterns 36 and 37, and simultaneously a fourth photoresist pattern 39 is formed to cover a part of the second area. The third photoresist pattern 38 is expanded in the second direction to the other part of the second area in order to increase the pattern uniformity. The third and fourth photoresist patterns 38 and 39 may be formed using the attenuated phase shift mask or the binary intensity mask.

As illustrated in FIG. 4C, the substrate 31 is etched using the first to fourth photoresist patterns 36 to 39 as an etch barrier, thereby forming a plurality of contact holes 40.

In the conventional art, since the capping layer 35 is not formed on the surface of the second photoresist pattern 37, the second photoresist pattern 37 of the second area to which the third photoresist pattern 38 is expanded may be lost, so that undesirable contact hole 40 may be formed. However, in accordance with the exemplary embodiment of the present invention, the capping layer 35 is formed on the surface of the second photoresist pattern 37, so that the contact hole 40 may be prevented from being formed improperly.

According to the present invention, an exposure process is performed such that a light with an amount smaller than the amount of a light irradiated onto an exposure area of a photoresist layer is also irradiated onto a non-exposure area of the photoresist layer, so that a capping layer may be formed on the surface of the photoresist layer using a freezing material. Consequently, an undesirable contact hole may be prevented from being formed.

While the present invention has been described with respect to the specific embodiments, it will be apparent to those skilled in the art that various changes and modifications may be made without departing from the spirit and scope of the invention as defined in the following claims.

What is claimed is:

1. A method for fabricating a semiconductor memory device, the method comprising:
forming a photoresist layer on a substrate;
performing an exposure process by illuminating a first area of the photoresist layer with a first amount of a light and illuminating a second area of the photoresist layer with a light of a second amount smaller than the first amount;
removing the first area of the photoresist layer to form a photoresist pattern; and
forming a capping layer on a surface of the photoresist pattern.

2. The method of claim 1, wherein the exposure process is performed using an attenuated phase shift mask.

3. The method of claim 2, wherein the attenuated phase shift mask exposes the first area of the photoresist layer and covers the second area of the photoresist layer.

4. The method of claim 1, wherein the second amount of the light is in a range of 6% to 30% of the first amount of the light.

5. The method of claim 1, further comprising:
performing a thermal treatment after the performing of the exposure process; and
performing a thermal treatment after the forming of the capping layer.

6. The method of claim 1, wherein the forming of the capping layer comprises:
coating a freezing material on a structure including the substrate;
performing a thermal treatment to form the capping layer on the surface of the photoresist pattern; and
removing a remaining freezing material.

7. A method for fabricating a contact hole of a semiconductor memory device, the method comprising:
forming a photoresist layer on a substrate having a first area and a second area;
performing an exposure process by illuminating an exposure area of the photoresist layer with a first amount of a light and illuminating a non-exposure area of the photoresist layer with a light of a second amount smaller than the first amount;
removing the exposure area of the photoresist layer to form a first photoresist pattern in the first area and a part of the second area and simultaneously form a second photoresist pattern covering the other part of the second area;
forming a capping layer on surfaces of the first and second photoresist patterns;
forming a third photoresist pattern crossing the first photoresist pattern in the first area and a part of the second area of the substrate and simultaneously forming a fourth photoresist pattern covering the other part of the second area; and
etching the substrate by using the first to fourth photoresist patterns as an etching barrier.

8. The method of claim 7, wherein the exposure process is performed using an attenuated phase shift mask.

9. The method of claim 7, wherein the second amount of the light is in a range of 6% to 30% of the first amount of the light.

10. The method of claim 7, further comprising:
performing a thermal treatment after the performing of the exposure process; and
performing a thermal treatment after the forming of the capping layer.

11. The method of claim 7, wherein the forming of the capping layer comprises:
coating a freezing material on a structure including the substrate;
performing a thermal treatment to form the capping layer on the surfaces of the first and second photoresist patterns; and
removing a remaining freezing material.

12. The method of claim 7, wherein the first photoresist pattern and the third photoresist pattern are formed in a line shape.

13. The method of claim 7, wherein the first photoresist pattern and the third photoresist pattern are expanded from the first area to the respective parts of the second area by crossing to each other.

14. The method of claim 7, wherein the first area includes a cell area and the second area includes a peripheral circuit area.
